(19) United States
(12) Patent Application Publication
(10) Pub. No.: US 2005/0253183 A1
(43) Pub. Date: Nov. 17, 2005

(54) Non-volatile semiconductor memory device and method of fabricating the same

(75) Inventors: Akira Umezawa, Tokyo (JP); Fumitaka Arai, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/091,408

(22) Filed: Mar. 29, 2005

(30) Foreign Application Priority Data
Apr. 22, 2004 (JP) 2004-127066

(51) Int. Cl. H01L 21/336

(52) U.S. Cl. 257/315

(57) ABSTRACT

A nonvolatile semiconductor memory device includes electrically rewritable memory cells formed in a cell array area of a semiconductor substrate. Each cell has spaced-apart source and drain regions, a charge storage layer overlying a channel between the source and drain, and a control gate overlying the charge storage layer. The device also includes a source line for common connection of the sources of those memory cells disposed along a word line by source-use conductors buried in mutually connected contact holes of the sources, drain-use conductors buried in contact holes of the drains of the cells, a transistor formed in a peripheral circuit area of the substrate to have a pair of source/drain regions and a gate electrode over a channel between the source/drain regions, and source/drain-use conductors buried in contact holes of the source/drain regions. Each source/drain buried conductor is longer than the drain-use buried conductor when viewing planarly.

### CROSS-REFERENCE TO RELATED APPLICATIONS

This application is based upon and claims the benefit of priority from the prior Japanese Patent Application No. 2004-127066, filed on Apr. 22, 2004, the entire contents of which are incorporated herein by reference.

### BACKGROUND OF THE INVENTION

1. Field of the Invention

The present invention relates to electrically data-rewritable nonvolatile semiconductor memory devices and methodology for fabricating the memory devices.

2. Description of the Related Art

Prior known semiconductor memory devices include nonvolatile memories with electrical data rewritability, such as electrically erasable programmable read only memory (EEPROM) chips. An EEPROM has memory cells with the so-called floating-gate MOSFET structure, wherein an electrical charge accumulation or storage layer (floating gate) and a control gate are stacked above a semiconductor substrate having a surface portion that serves as a channel region, with a dielectric film being interposed between the floating and control gates. A memory cell is a unit element that stores therein a one (1) bit of data. A plurality of such memory cells are disposed and organized into a matrix of rows and columns, thus providing a cell array.

A flash memory is an EEPROM capable of erasing all bits of cell data at a time—namely, “all-at-a-time” data erasure. The flash memory is increasing in storage capacity (for example, 64 megabits) due to recent advances in micro-fabrication process technologies. As in dynamic random access memories (DRAMs) and static random access memories (SRAMs), the flash memory comes with various kinds of functions, such as those in a page mode and a burst mode. It is required by end users that these functions increase in high-speed performance. To meet the requirement, it is important to achieve an ability to transfer input and output (IO) data between the flash memory and its associated central processor unit (CPU). Additionally, while the flash memory is programmed prior to product shipment, such programming tales time as the flash memory is slow in data writing and erasing operations. This would result in an increase in production cost of the flash memory.

The flash memory is typically designed to perform a data erase operation in such a way as to apply a high voltage via a source line to respective source regions of a group of memory cells as selected for all-at-once erase, and then draw electrons out of their charge storage layers by tunnel effects. In order to reduce the electrical resistivity of such source line for enhancing high-speed performances, the source line is buried in a groove which is formed along a word line to couple together contact holes of the source regions of the memory cell group selected for the all-at-once erase. An example of this approach is disclosed, for example, in Japanese Laid-Open Patent Application No. 2000-91450 (“JP-A-2000-91450”), Paragraph “0021” and FIGS. 1-2. This source line is formed by using a high-melting point metal layer, called local interconnection (LI) layer. This LI layer is provided in order to achieve miniaturization or scale-down of semiconductor circuit elements, such as memory cells. Examples of a semiconductor device using such LI layer are found, for example, in JP-A-5-136086 (Paragraphs “0002” to “0004” and FIGS. 1-3) and JP-A-2002-299472 (Paragraphs “0016” to “0017” and FIG. 4).

Incidentally, as in other types of semiconductor memories, the flash memory also is such that a cell array and peripheral circuitry (e.g., decoders) are mounted together on the same semiconductor substrate. Due to the scale-down of memory cells, the cell array decreases in size accordingly. This makes it necessary to shrink the peripheral circuitry also, which is closely related in layout to the cell array.

Unfortunately, a problem arises which follows. The peripheral circuitry is made up of transistors, which have device parameters (such as gate oxide film thickness, minimum gate width, junction breakdown voltage, and others) that are inflexibly determined depending upon an operating voltage of memory cells. Due to this, the transistors of the peripheral circuit have been difficult in scaling (proportional shrinkage). As the performances of the peripheral circuit transistors are closely related to speed-up of read, write and erase operations of memory cells, it is a key challenge to develop a technique for enhancing the transistor performances upon shrinkage of the peripheral circuit.

### BRIEF SUMMARY OF THE INVENTION

In accordance with one aspect of the present invention, a nonvolatile semiconductor memory device includes an array of electrically data-rewritable nonvolatile memory cells each having spaced-apart source and drain regions formed in a cell array area of a semiconductor substrate, an electrical charge storage layer formed above a channel region between the source and drain regions, and a control gate overlying the charge storage layer. The device also includes a source line for common connection of source regions of a plurality of ones of the memory cells disposed along a word line by source-use buried conductive portions as buried in mutually connected contact holes of the source regions, drain-use buried conductive portions buried in contact holes of drain regions of the plurality of ones of the memory cells, a transistor having a pair of spaced-apart source/drain regions formed in a peripheral circuit area of the semiconductor substrate and a gate electrode formed over a channel region between the source/drain regions, and source/drain-use buried conductive portions buried in contact holes of the source/drain regions and each formed to be longer than any one of the drain-use buried conductive portions when planarly looking at them.

In accordance with another aspect of this invention, a nonvolatile semiconductor memory device is provided, which is similar to the above-noted memory device, except that the “source/drain-use buried conductive portion that is buried in contact holes of the source/drain regions and that is formed to be longer than the drain-use buried conductive portions when looking at them planarly” is replaced by a “source/drain-use buried conductive portion being buried in a contact hole of the source/drain region and having a rectangular flat face.

According to still another aspect of the invention, a nonvolatile semiconductor memory device fabrication method includes: forming electrically data rewritable nonvolatile memory cells each having spaced-apart source and drain regions formed in a cell array area of a semiconductor substrate, an electrical charge storage layer formed above a channel region between the source and drain regions, and a control gate overlying the charge storage layer and while substantially simultaneously forming a transistor having a pair of spaced-apart source/drain regions formed in a peripheral circuit area of the semiconductor substrate and a gate electrode formed over a channel region defined between the source/drain regions; forming an interlayer dielectric layer above the semiconductor substrate in such a manner as to cover the memory cells and the transistor; simultaneously performing, by selective removal of the interlayer dielectric layer, formation of contact holes at the drain regions, formation of contact holes at the source regions of a plurality of ones of the memory cells which are laid out along a word line so that the contact holes are coupled together, and formation of contact holes at the source/drain regions, which contact holes are longer than the contact holes of the drain regions when looking at them planarly; and simultaneously performing formation of drain-use buried conductive portions in the contact holes of the drain regions, formation of source-use buried conductive portions for use as a source line for common connection of respective source regions in the contact holes of the source regions of the plurality of ones of the memory cells, and formation of source/drain-use buried conductive portions in the contact holes of the source/drain regions.

In accordance with a further aspect of the invention, a nonvolatile semiconductor memory device fabrication method is similar to the above-stated method with the step of “simultaneously performing, by selective removal of the interlayer dielectric layer, formation of contact holes at the drain regions, formation of contact holes at the source regions of a plurality of ones of the memory cells which are laid out along a word line so that the contact holes are coupled together, and formation of contact holes at the source/drain region, which contact holes are longer than the contact holes of the drain regions when looking at them planarly” being replaced with a step of “simultaneously performing, by selective removal of said interlayer dielectric layer, formation of contact holes at the drain regions, formation of contact holes at the source regions of a plurality of ones of the memory cells which are laid out along a word line so that the contact holes are coupled together, and formation of contact holes each having a rectangular flat face at the source/drain region.”

### BRIEF DESCRIPTION OF THE DRAWINGS

FIG. 1 is a diagram pictorially showing a cross-sectional structure of a memory cell in accordance with an embodiment of the invention.

FIG. 2 is an equivalent circuit diagram showing one part of a cell array in accordance with the embodiment.

FIG. 3 is a circuit block diagram of a flash memory in accordance with the embodiment.

FIG. 4 is an equivalent circuit diagram of a column decoder and a column gate of FIG. 3.

FIG. 5 is a diagram showing a planar layout pattern of one part of the cell array in accordance with the embodiment.

FIG. 6 is a diagram showing a planar layout of part of the column gate in accordance with the embodiment.

FIG. 7A shows a pictorial cross-sectional view of the cell array of FIG. 5 as taken along line A1-A2.

FIG. 7B is a sectional view of the FIG. 5 cell array along line B1-B2.

FIG. 7C is a sectional view of the structure of FIG. 6 along line C1-C2.

FIG. 7D is a sectional view of FIG. 6 along line D1-D2.

FIG. 8 is a diagram showing a plan view of a transistor making up the column gate in accordance with the embodiment.

FIG. 9 is a sectional view of the transistor of FIG. 8 as taken along line IX(a)-IX(b).

FIGS. 10A to 10D illustrate, in cross-section, some major portions at a first process step of a fabrication method of the flash memory in accordance with the embodiment, which portions correspond to those shown in FIGS. 7A to 7D, respectively.

FIGS. 11A to 11D illustrate, in cross-section, some major portions at a second step of the fabrication method of the flash memory in accordance with this embodiment, which portions correspond to those shown in FIGS. 7A-7D, respectively.

FIGS. 12A to 12D depict, in cross-section, some major portions at a third step of the flash memory fabrication method in accordance with the embodiment, which portions correspond to those of FIGS. 7A-7D, respectively.

FIGS. 13A to 13D show, in cross-section, some major portions at a fourth step of the flash memory fabrication method in accordance with the embodiment, which portions correspond to those of FIGS. 7A-7D, respectively.

FIG. 14 is a plan view of a cell array area at the above-noted second step of the flash memory fabrication method.

FIG. 15 is a plan view of a peripheral circuit area at the second step of the fabrication method.

FIG. 16 is a sectional view of part of a one-cell/two-transistor (“1C2T”) NAND type cell array in accordance with an embodiment.

FIG. 17 is a diagram showing a planar layout pattern of part of the cell array shown in FIG. 16.

FIG. 18 is a sectional view of a one-cell/three-transistor (1C3T) NAND cell array in accordance with an embodiment.

FIG. 19 is a diagram showing a planar layout of part of the cell array of FIG. 18.

FIG. 20 is a perspective view of an electronic device for use with an electronic card in accordance with an embodiment.

FIG. 21 is a diagram showing a basic configuration of a digital still camera, which is a first example of the electronic device in accordance with the embodiment.

FIG. 22A is a diagram showing a video camera which is a second example of the electronic device in accordance with the embodiment.

FIG. 22B is a diagram showing a television set which is a third example of the electronic device in accordance with the embodiment.

FIG. 22C shows an audio equipment which is a fourth example of the electronic device in accordance with the embodiment.

FIG. 22D shows a video game console which is a fifth example of the electronic device in accordance with the embodiment.

FIG. 22E shows an electronic music instrument which is a sixth example of the electronic device in accordance with the embodiment.

FIG. 22F shows a mobile telephone handset which is a seventh example of the electronic device in accordance with the embodiment.

FIG. 22G shows a personal computer (PC) which is an eighth example of the electronic device in accordance with the embodiment.

FIG. 22H shows a personal digital assistant (PDA) which is a ninth example of the electronic device in accordance with the embodiment.

FIG. 22I shows a voice recorder which is a tenth example of the electronic device in accordance with the embodiment.

FIG. 22J shows a PC card which is an eleventh example of the electronic device in accordance with the embodiment.

### DETAILED DESCRIPTION OF THE INVENTION

A flash memory device of the NOR type in accordance with one embodiment of this invention will be described below. This NOR flash memory has an array of memory cells and an on-chip peripheral circuit, including a column gate made up of transistors. One feature of this memory is that buried conductive portions connected to source/drain regions of the column gate transistors—say, “source/drain-use buried conductors—are formed to be longer than buried conductive portions for connection to the drain regions of memory cells (i.e., drain-use buried conductors), when looking at them planarly. For the understanding of this feature, the flash memory device of the NOR type and a circuit block configuration of the flash memory will first be explained. Accordingly, an explanation of this embodiment will be subdivided into several parts or “topics” titled as follows: 1) “NOR Flash Memory,” 2) “Flash Memory Circuit Blocks,” 3) “Cell Array and Column Gate Structure,” 4) “Flash Memory Fabrication Method,” 5) “1C2T/1C3T-NAND Flash Memories” and 6) “Applying to Electronic Cards and Electronic Devices.”

Note here that in the drawings for explanation of this embodiment, like components are designated by like reference characters, with repetitive explanations eliminated.

### NOR Flash Memory

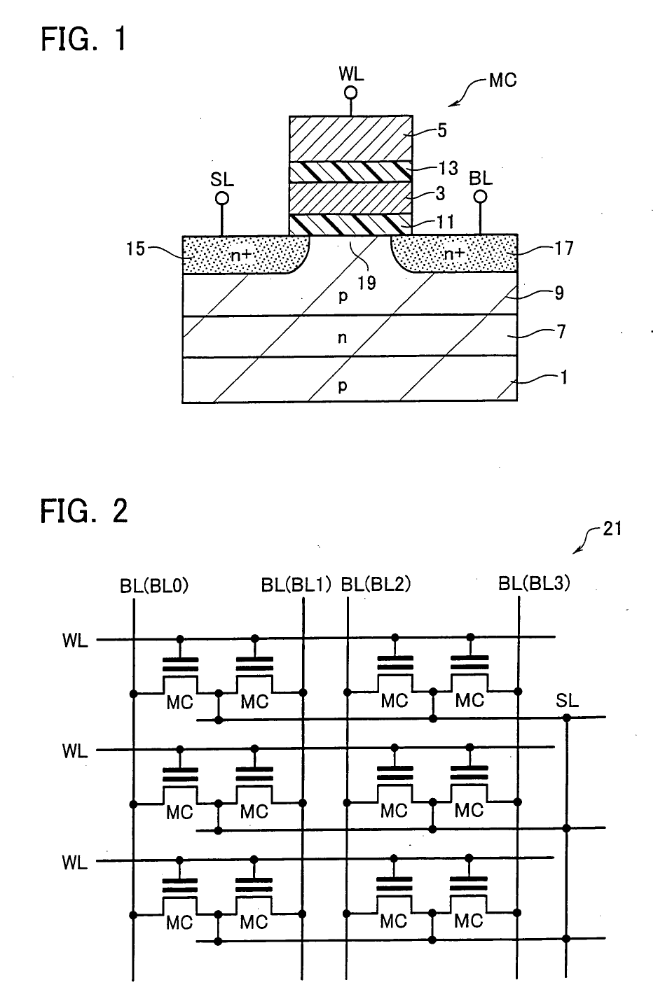

FIG. 1 is a diagram pictorially showing a cross-sectional structure of a memory cell in accordance with this embodiment. FIG. 2 is an equivalent circuit diagram showing a portion of a cell array in accordance with this embodiment. As shown in FIG. 1, a nonvolatile memory cell MC is structured from a metal insulator semiconductor field effect transistor (MISFET) having an electrical charge accumulation or “storage” layer 3 and a control gate 5, which are insulatively stacked or multilayered above a semiconductor substrate 1 of the p conductivity type. More specifically, a semiconductor well region 7 of the n conductivity type is formed in the p-type semiconductor (e.g. silicon) substrate 1. In this n-type well 7, a p-type well 9 is formed. In this p-type well 9, the memory cell MC is formed.

The charge storage layer 3 of memory cell MC is made of poly-silicon and is formed above the p-type well 9 with a gate insulating dielectric layer 11 interposed therebetween. The control gate 5 of cell MC is made of polysilicon and is formed above charge storage layer 3 with a dielectric layer (e.g. oxide/nitride/oxide or “ONO” film) 13 sandwiched therebetween. Cell MC also has a pair of heavily-doped n (n⁺) type source region 15 and drain region 17, which are formed in the p-well 9 to be self-aligned with the control gate 5. The source region 15 and drain region 17 are laterally spaced apart from each other to define therebetween a channel region 19.

The control gate 5 is continuously formed in one direction and is thus for use as a word line WL. The drain region 17 is connected to a bit line BL, while the source region 15 is coupled to a source line SL.

As shown in FIG. 2, a cell array 21 includes memory cells MC, which are laid out at respective crossing points or “intersections” of word lines WL and bit lines BL extending at right angles to each other. In the NOR type flash memory, the individual memory cell MC has its drain region that is connected to a bit line. The p-well 9 of FIG. 1 is independently formed per unit of “all-at-a-time” data erasure. This unit will be referred to as a block hereinafter. Source regions 15 of all memory cells MC within a block are common-coupled together to a source line SL. Accordingly, as will be explained later, per-block independent bit lines BL serve as local bitlines, one of which is selectively connected to an upper-level main bitline.

An exemplary operation of the NOR flash memory is as follows. To write or “program” data, a write voltage of 9 volts (V) is applied to a word line WL that is selected for data write while setting the p-well 9 and source line SL at 0V and also applying to a bit line BL a voltage of 4.5 or 0V, which is determined depending upon whether the data to be written is a logic “0” or “1.” At a memory cell that is given logic “0” data, hot electrons are created near its drain region 17 due to the presence of a strong lateral-directional electric field between the source and drain regions 15 and 17 thereof. These hot electrons are injected into the charge storage layer 3. In the case of logic “1” data, such electron injection hardly takes place.

The electron injection into the charge storage layer 3 results in the cell's threshold voltage becoming higher. This is a logic “0” data storage state. In the case of logic “1” data, no hot electrons are produced. Thus, no electrons are injected into the charge storage layer 3, causing the cell to stay in an erase state—that is, retain a logic “1” data storage state that is low in threshold voltage.

For data erasure, “all-at-once” erase is performed on a per-block basis. At this time, a voltage of 10V is applied to the p-well 9 and source line SL of a block that is selected together with the n-well 7. A voltage of −7V is applied to all word lines WL within the selected block while at the same time setting all bit lines BL within the selected block in an electrically floating state. With such voltage settings, a large electric field is applied to the gate insulator layers 11 of the memory cells MC within the block, causing the electrons of the charge storage layer 3 of each cell to give off toward the channel region 19 side due to the flow of a tunnel current, known as Fowler-Noldheim (FN) current. Thus every cell within the selected block is in the erase state, which is equivalent to the logic “1” data state.

During data reading, let the p-well 9 and source line SL of a selected block be set at 0V while setting a bit line BL at 0.8V. A read voltage is applied to a selected word line WL. The read voltage is set at an intermediate value that is midway between the threshold voltages corresponding to logic “0” and “1” data bits—for example, 4.75V. Then, a sense amplifier connected to the bitline BL is rendered operative to determine whether the memory cell MC's current pull-up is present or absent.

### Flash Memory Circuit Blocks

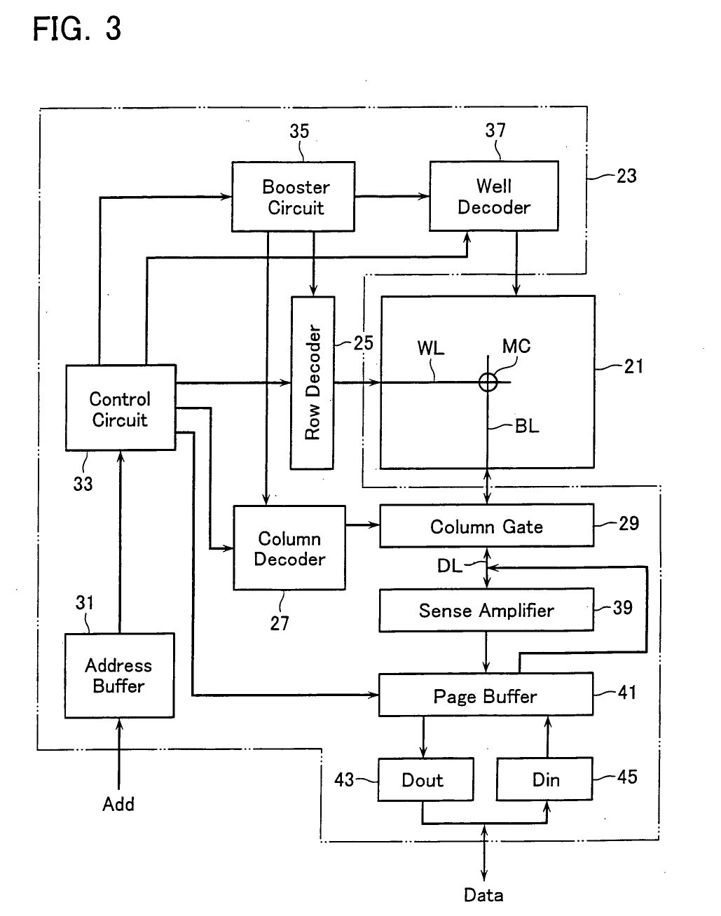

FIG. 3 is a circuit block diagram of the flash memory in accordance with this embodiment. This flash memory is such that its memory cell array 21 and peripheral circuitry 23 are formed on the same semiconductor substrate—that is, the p-type silicon substrate 1 shown in FIG. 1. This substrate has a surface including a cell array area in which the cell array 21 is formed, and a peripheral circuit area in which the peripheral circuit 23 is mounted. A configuration of the peripheral circuit 23 will be explained below.

A row decoder 25 is provided for wordline selection of the cell array 21. A column decoder 27 is provided for bitline selection. Also provided is a column gate 29 that is selectively activated by the column decoder 27. An address signal is sent via an address buffer 31 to a control circuit 33. Inside row and column address signals are transferred to the row decoder 25 and column decoder 27, respectively.

For data write and erase, a voltage with its potential level raised up from the power supply voltage is used. To do this, a booster circuit 35 is provided, which is controlled by the control circuit 33 in a way pursuant to operation modes. An output voltage of the booster circuit 35 is supplied to word lines WL and bit lines BL by way of the row decoder 25 and column decoder 27. Additionally, since the cell array 21 is divided into blocks with respect to each unit of all-at-once erase, the peripheral circuit 23 includes a well decoder 37 for control of the well potential of each block.

The flash memory of this embodiment is operable in a page mode. Thus this flash memory has a sense amplifier circuit 39, including sense amplifiers each being connected to a bundle of data lines DL that correspond to a one page (e.g., 128 bits). Data as read by a sense amp is held in a page buffer 41. Under control of the control circuit 33, a one page of data bits are randomly accessed for output via a data output buffer 43. Write data is sent via a data input buffer 45 and then temporarily retained in the page buffer 41, for later transfer to a data line DL under the control of control circuit 33.

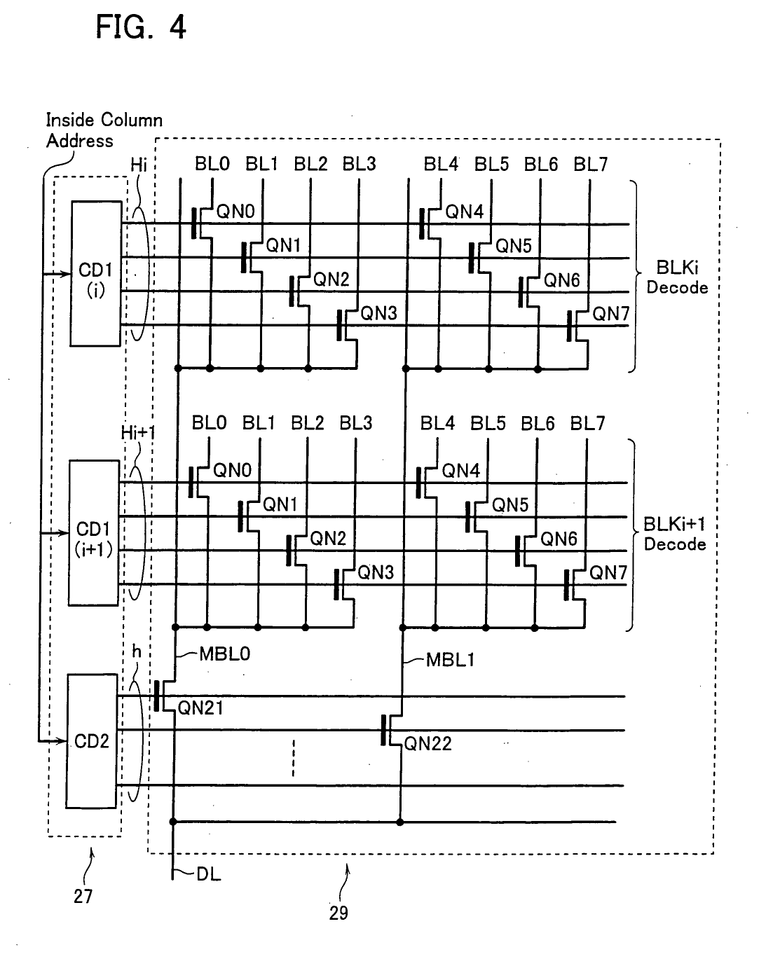

FIG. 4 shows equivalent circuit configurations of the column decoder 27 and column gate 29 of FIG. 3. As stated previously, the cell array 21 is divided into blocks BLKi, BLKi+1, . . . . Each block has a plurality of parallel bit lines BL, which are organized into groups each having four bitlines BL0 to BL3, BL4-BL7, . . . , for example. Any one of these four bitlines is selectively connectable to a main bitline MBL0, MBL1, . . . via a corresponding one of column gate transistors QN0-QN3, QN4-QN7, . . . The column decoder 27 has column decode circuits CD1, each of which performs bitline selection of a block associated therewith, and also has a column decode circuit CD2 for performing selection of a main bitline.

The individual column decode circuit CD1 has its output lines for use as column select lines Hi, Hi+1, . . . , which are for control of the gates of column gate transistors QN0-QN3, QN4-QN7, . . . . The column decode circuit CD2 has output lines that serve as column select lines “h” for control of the gates of column gate transistors QN21, QN22, . . . , which are for performing main bitline selection. With the above, a selected bitline BL of a selected block is connected to a main bitline MBL via a column gate transistor that is activated by a column select line Hi, Hi+1, . . . . The main bitline MBL is to be coupled to a data line DL via a column gate transistor that is activated by one of the column select lines h.

### Cell Array and Column Gate Structure

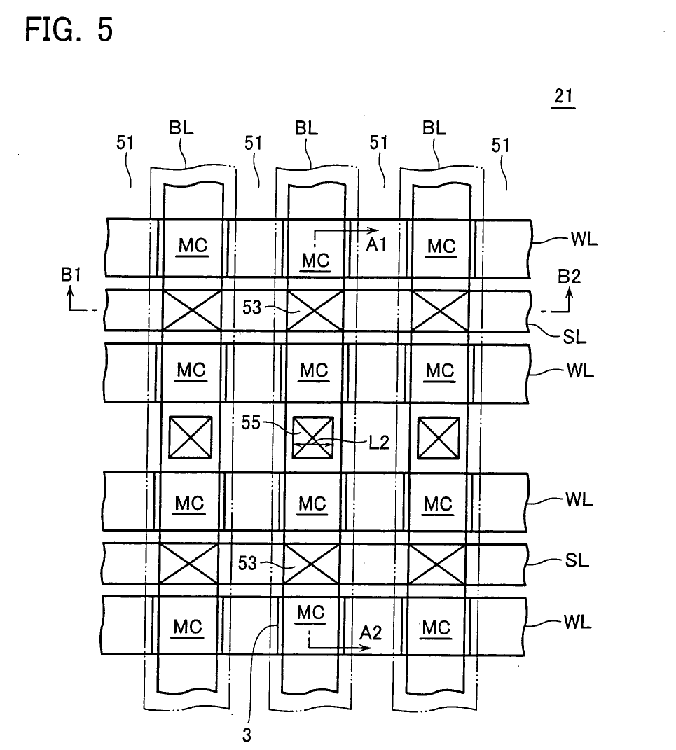

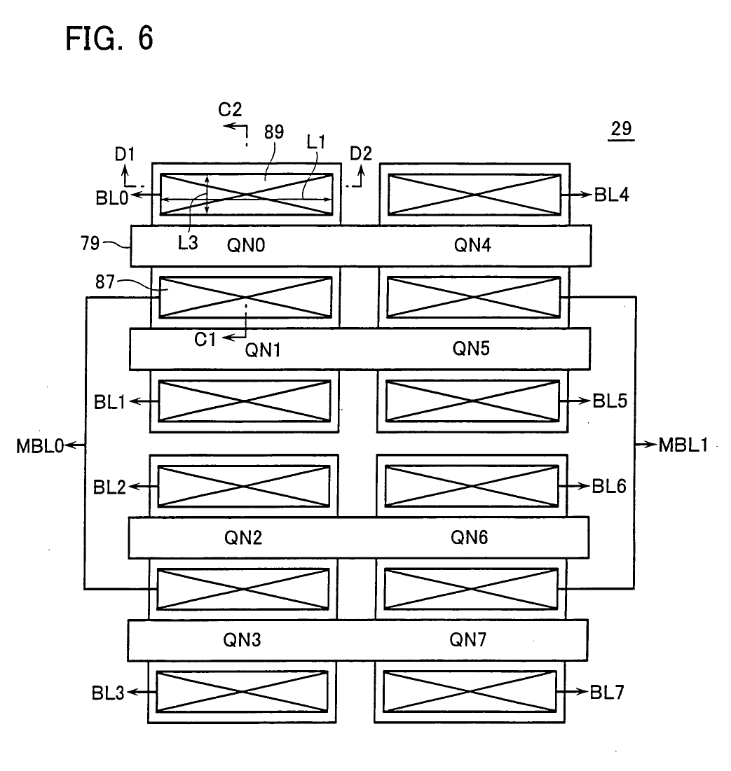

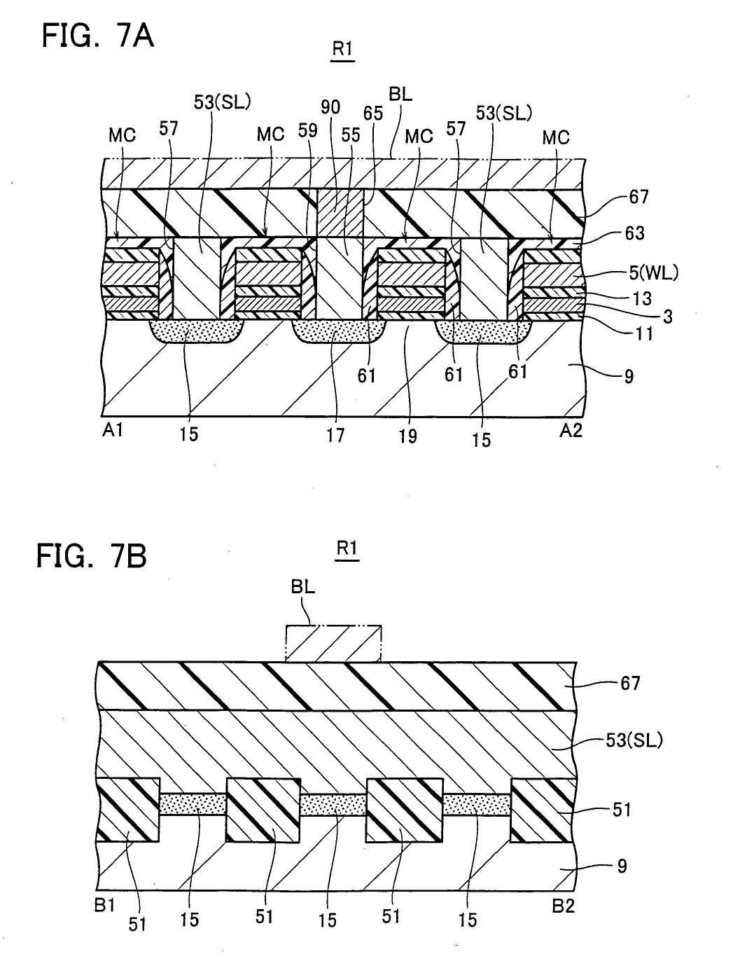

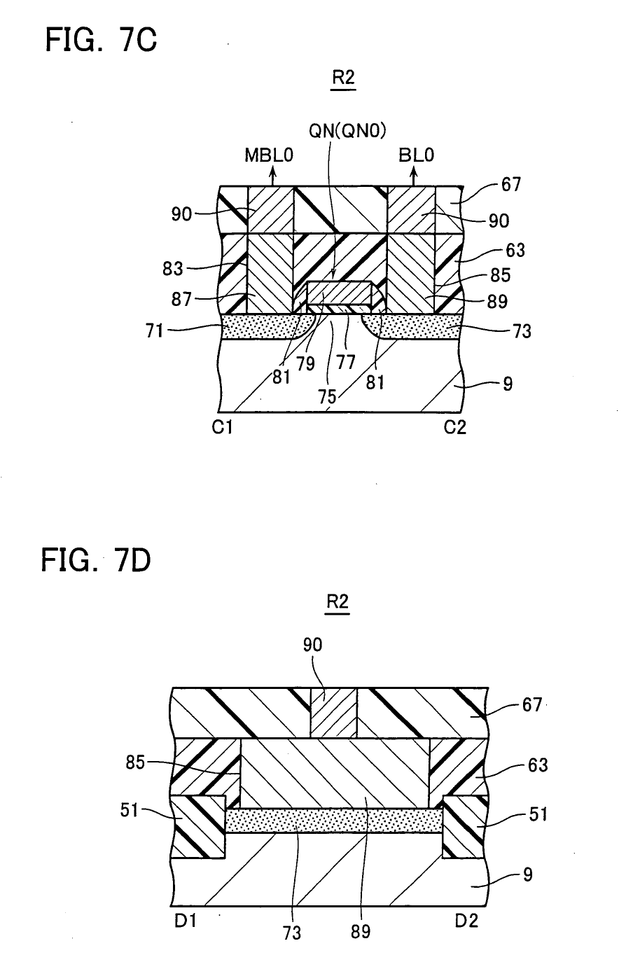

FIG. 5 shows a planar layout pattern of part of the cell array 21. FIG. 6 depicts a planar layout of part of the column gate 29. FIG. 7A is a cross-sectional view of the layout structure of FIG. 5 as taken along line A1-A2. FIGS. 7B to 7D are sectional views of it along lines B1-B2, C1-C2 and D1-D2, respectively. In FIGS. 7A-7D, reference character R1 designates a cell array area, whereas R2 denotes a peripheral circuit area. Note here that in FIGS. 7A-7D and FIGS. 9, 10A-10D through 13A-13D, the p-type silicon substrate 1 and n-type well 7 shown in FIG. 1 are omitted from illustrations.

A structure of the cell array 21 will first be explained with reference to FIGS. 5 and 7A-7B. Memory cells MC are disposed at intersections of word lines WL and bit lines BL. The structure of memory cell MC is as has been discussed previously in conjunction with FIG. 1. Element isolating dielectric layers 51 are laid out at intervals so that these extend in a direction parallel to the bit lines BL.

Alternately formed between word lines WL are source-use buried conductive portions 53 which are for connection to source regions 15 and drain-use buried conductive portions 55 for connection to drain regions 17. A source region 15 is in contact with a corresponding one of the source-use buried conductors 53 and extends to reach a location underlying a one side part of a charge storage layer 3. A drain region 17 is contacted with a drain-use buried conductor 55 and extends to lie beneath the other side part of the charge storage layer 3. Source regions 15 of a plurality of memory cells MC disposed along each word line WL have contact holes 57 that are coupled to each other, at which a source-use buried conductor 53 is embedded. A source line SL for common connection of the source regions 15 of a plurality of memory cells MC laid out along a word line WL is formed by source-use buried conductors 53. Designing the source-use buried conductors 53 to have this structure makes it possible to reduce the electrical resistivity of source line SL without having to form suicides at the source regions 15. On the other hand, the drain-use buried conductors 55 are embedded in contact holes 59 of drain regions 17. The buried conductors 53 and 55 are portions of a local interconnection (LI) layer which contains a high-melting point metal, such as tungsten for example.

As shown in FIG. 7A, sidewall dielectric layers 61 are formed on sidewalls of the charge storage layer 3 and control gate 5 of a memory cell MC. An interlayer dielectric (ILD) layer 63 is provided to cover memory cells MC. Contact holes 57 and 59 are formed in the ILD layer 63. On this ILD layer 63, another ILD layer 67 is provided to have a through-going holes, one of which is indicated by numeral 65 in FIG. 7A. This through-hole 65 is filled with a conductive plug 90 for connection to its underlying drain-use buried conductor 55. Bit lines BL are formed on ILD layer 67 although only one of them is visible in FIG. 7A, which is connected to a drain region 17 through the conductive plug 90 and drain-use buried conductor 55.

An explanation will next be given of a configuration of the column gate circuit 29 with reference to FIGS. 6 and 7C-7D. There are shown in FIG. 6 certain ones of the transistors making up the column gate 29—i.e., column gate transistors QN0-QN7. Two adjacent ones of the column gate transistors QN0-7 commonly have or shares one of paired source/drain regions. To this shared source/drain region, a main bitline MBL0, MBL1 is connected. The remaining “non-shared” source/drain regions are connected to corresponding bit lines BL0-BL7. Note here that the source/drain region is an impurity-doped region that functions as at least either one of the source and drain of a memory cell transistor.

The transistors QN0-7 are the same in structure as one another. As an example, the transistor QN0 has a pair of spaced-apart source/drain regions 71 and 73 formed in the p-well 9 of semiconductor substrate, a channel region 75 defined therebetween, and a gate electrode 79 that overlies the channel region 75 with a gate insulation layer 77 between the channel 75 and gate 79. The gate 79 has a side wall on which a sidewall dielectric layer 81 is provided.

An interlayer dielectric (ILD) layer 63 is formed to cover the gate electrode 79. ILD layer 63 has contact holes 83 and 85 as formed therein to expose the source/drain regions 71 and 73. Each contact hole 83, 85 is filled with a source/drain-use buried conductive portion 87, 89. The source/drain-use buried conductor 87, 89 extends in a direction parallel to the gate electrode 79. The buried conductor 87, 89 is the one that was formed simultaneously during fabrication of the source-use buried conductors 53 and drain-use buried conductors 55. Thus the conductor 87, 89 is a local interconnection (LI) layer containing a high-melting point metal, such as tungsten as an example.

An ILD layer 67 is formed on the ILD layer 63. ILD layer 67 has buried conductive plugs 90 for connection to the source/drain-use buried conductors 87 and 89 respectively.

Here, some major effects of this embodiment will be explained. In NOR flash memories, when writing a logic “0” data bit into a memory cell, a write operation is performed in such a way as to generate hot electrons near a drain region for injection into a charge storage layer. In this embodiment, when writing logic “0” data, the voltage of 4.5V is applied to the drain region 17 of a memory cell MC (for detail, see the previous section titled “NOR Flash Memory”). This requires that the voltage of a bit line BL be set at 4.5V. Thus it is necessary for the transistor QN of column gate 29 to supply a 4.5-V voltage to the bitline BL. As this 4.5-V voltage is higher than the power supply voltage, the booster circuit 35 of FIG. 3 is used to potentially raise the supply voltage to provide a boosted voltage, which is then supplied to the column gate 29. If the source/drain-use buried conductor 87, 89 is large in parasitic capacitance, then the boosted voltage drops down, resulting in a likewise decrease in the voltage being supplied to the bitline BL. This causes delay of a write operation. Enlarging the gate width of column gate transistor QN makes it possible to avoid such voltage drop-down. However, the transistor QN becomes larger in area accordingly. This results in an increase in area of semiconductor chip on which the flash memory is formed. Consequently, it is desired to enhance the performance of the transistor QN of column gate 29, thereby enabling a desired voltage to be supplied to the bitline BL.

According to this embodiment, the transistor performance enhanceability is achieved. This will be explained with reference to FIGS. 5-6 below. Since the source/drain-use buried conductor 87, 89 extends in the direction parallel to the gate electrode 79, the conductor 87, 89 has a rectangular planar surface shape as shown in FIG. 6. On the contrary, the drain-use buried conductor 55 has a square planar face. The source/drain-use buried conductor 87, 89 has a long side with a length L1, which is greater than that of one side L2 of drain-use buried conductor 55 (additionally, the buried conductor 87, 89's short side length L3 is substantially the same as that of one side L2 of buried conductor 55). As stated above, the source/drain-use buried conductor 87, 89 is formed to be longer than the drain-use buried conductor 55 when planarly looking at them.

Accordingly, unlike a case where the face area of the source/drain-use buried conductor 87, 89 is simply made equal to that of drain-use buried conductor 55, it becomes possible to enlarge the face area of source/drain-use buried conductor 87, 89. Thus it is possible to reduce the parasitic resistance of source/drain-use buried conductor 87, 89. This results in an improvement in performance of the transistor QN of column gate 29 (one example of peripheral circuit). This in turn makes it possible to supply a desired voltage to a bitline(s) BL.

Although the explanation above is directed to the transistor QN for use as a component of the column gate 29, those transistors for use as components of decoders (row decoder 25, column decoder 27, and source well decoder 37 of FIG. 3) also operate with a voltage as boosted from the power supply voltage. Thus it is possible to apply the features of this embodiment to the transistors making up the decoders.

It is noted here that while this embodiment may be limitedly applied to specific circuitry made up of those transistors operable with a voltage boosted from the supply voltage, such as the column gate 29 and decoders, this embodiment may also be applicable to all of the transistors making up the peripheral circuit. With such an arrangement, it is possible to reduce the parasitic resistance of those transistors making up circuit modules of the peripheral circuit which operate with the supply voltage (for example, the address buffer 31, data output buffer 43, and data input buffer 45 of FIG. 3).

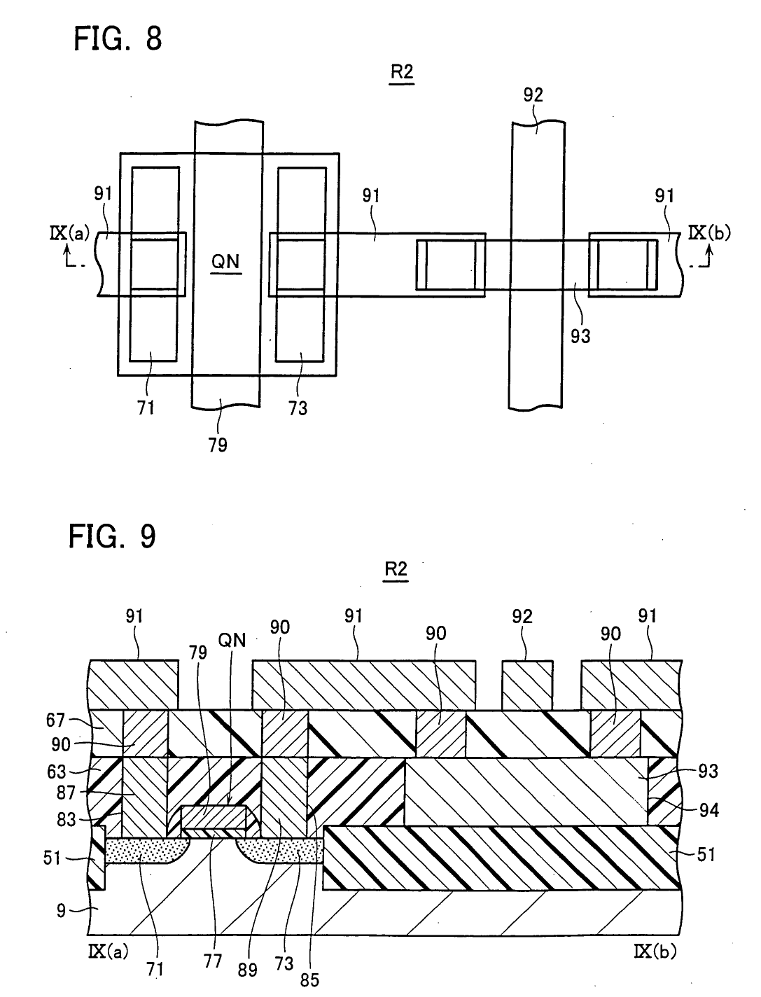

So far, there has been discussed one specific case where the local interconnection (LI) layer is utilized for the source/drain-use buried conductor 87, 89. This LI layer is also utilizable for wiring lines of the peripheral circuitry. This will be explained using FIGS. 8-9 below. FIG. 8 depicts a plan view of a transistor making up the column gate 29. FIG. 9 is a pictorial representation of a cross-section taken along line IX(a)-IX(b) of FIG. 8.

Electrical interconnect wiring lines 91 and 92 are formed on the interlayer dielectric (ILD) layer 67. The wire 91 is connected to the source/drain region 71, 73 of a transistor QN. The wire 92 is coupled to none of the source/drain regions 71 and 73. Wire 92 is placed in a route along which wire 91 extends. In order to prevent wire 91 from crossing wire 92 at the same level, a wire-use buried conductive portion 93 that is an LI layer is formed on an element isolating dielectric layer 51 which is beneath wire 92. This buried conductor 93 is connected by conductive plugs 90 to the wire 91.

As apparent from the foregoing, according to this embodiment, the wire-use buried conductor 93 of the LI layer is used to prevent the wire 91 from directly crossing the wire 92. Thus it is possible to increase the flexibility of layout of on-chip wires placed at upper levels than the wires 91-92. Note here that the wire-use buried conductor 93 is embedded in a wiring groove 94 that is provided in the ILD layer 63. The wiring groove 94 is formed at the same time during formation of the contact holes 83 and 85. The wire-use buried conductor 93 and source/drain-use buried conductor 87, 89 are formed simultaneously.

### Flash Memory Fabrication Method

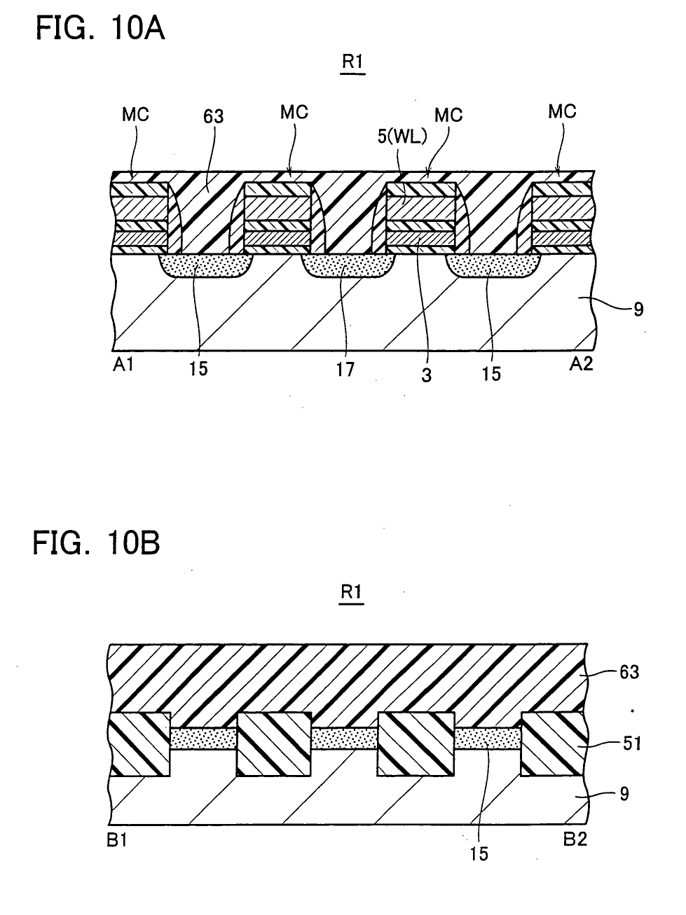

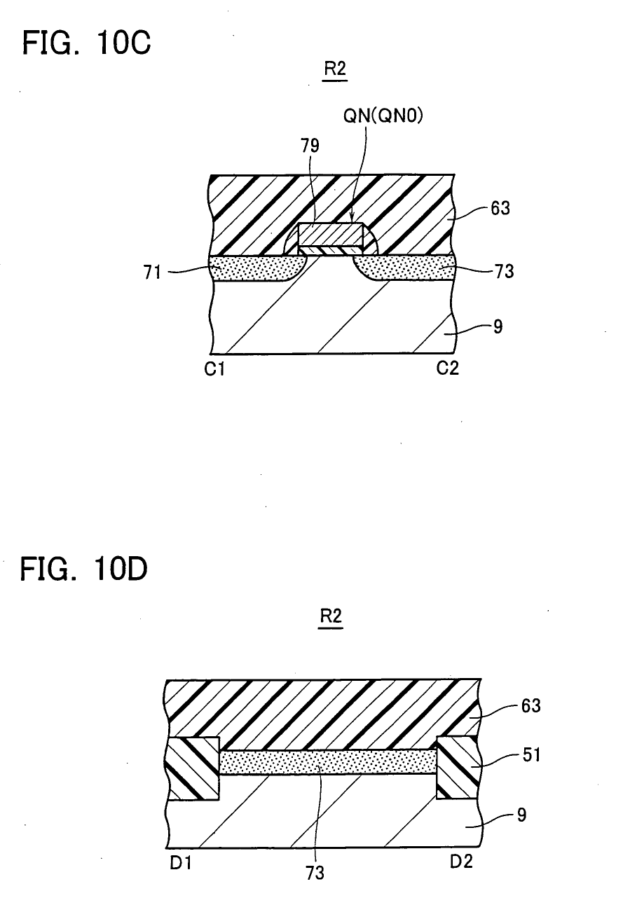

FIGS. 10A-10D to 13A-13D are diagrams showing, in the order of process steps, a fabrication method of the flash memory in accordance with this embodiment, which diagrams correspond to the cross-sections of FIGS. 7A-7D, respectively. Firstly, as shown in FIGS. 10A-10D, memory cells MC and column gate transistors QN are formed on a p-type well region 9 of a semiconductor substrate. Then, an interlayer dielectric (ILD) layer 63 made of a silicon oxide film is formed, for example, by chemical vapor deposition (CVD) techniques in such a manner as to cover the memory cells and transistors. The ILD layer 63 is then polished for surface planarization by chemical-mechanical polish (CMP) techniques, by way of example.

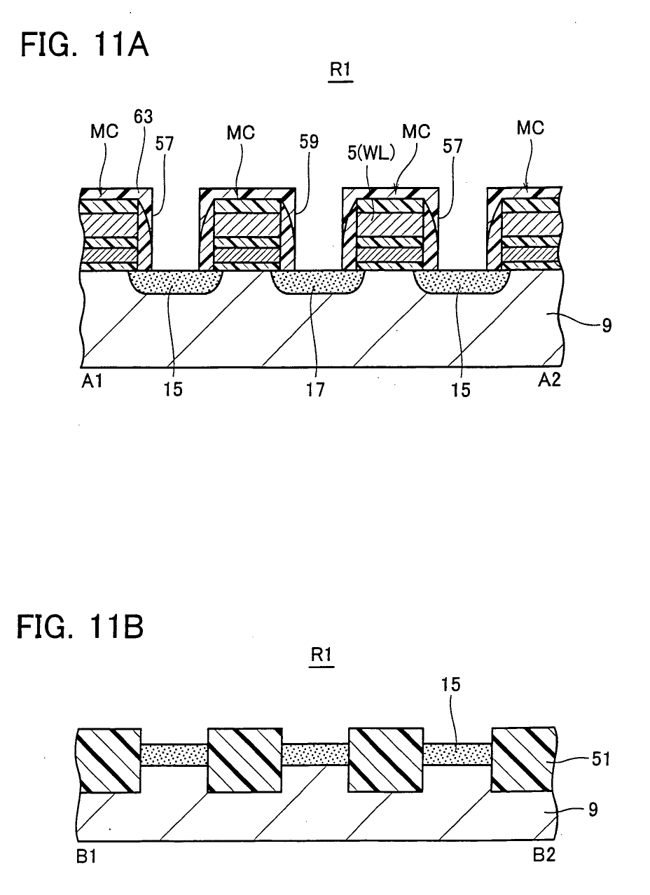

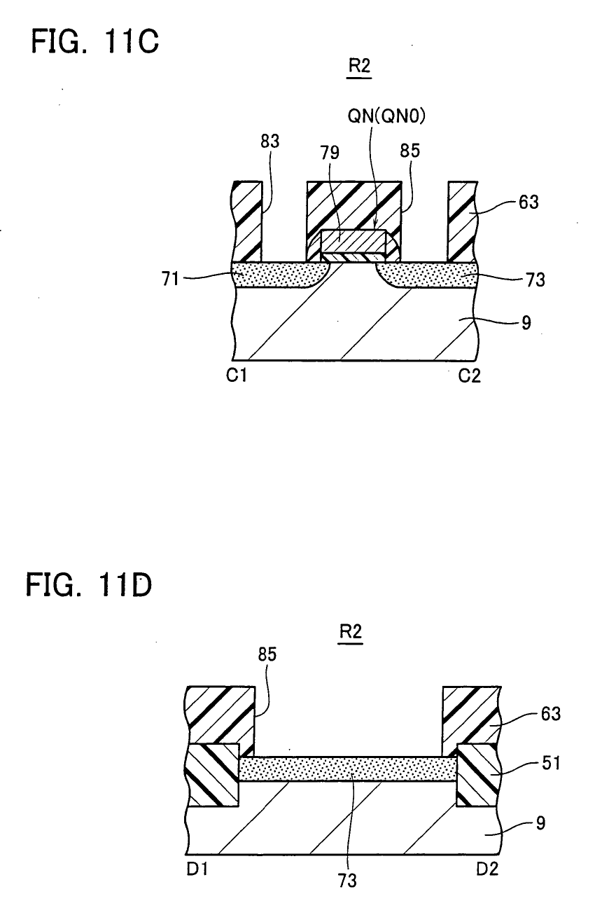

As shown in FIGS. 11A-11D, the ILD layer 63 is selectively removed away by photolithography and etching processes. Whereby, contact holes 59 are formed at drain regions 17 of the memory cells MC, while contact holes 57 are formed at source regions 15 thereof. Simultaneously, contact holes 83 and 85 are formed at source/drain regions 71 and 73 of the column gate transistors QN.

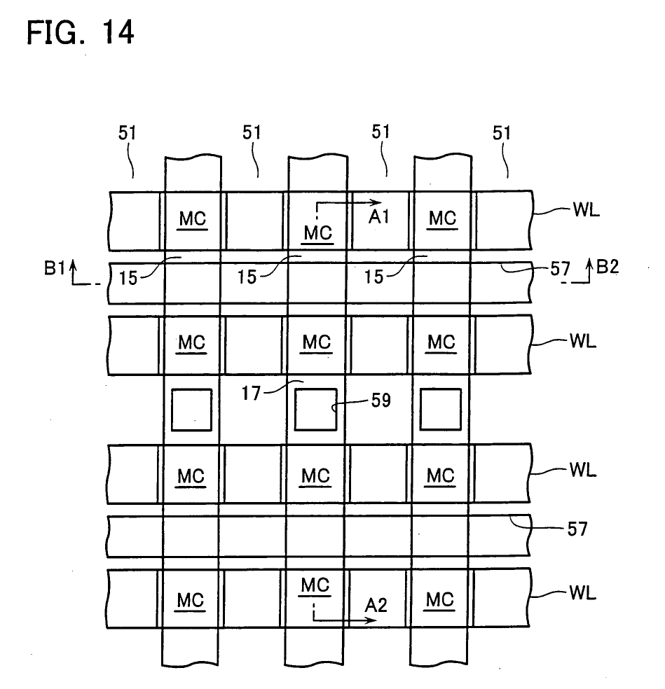

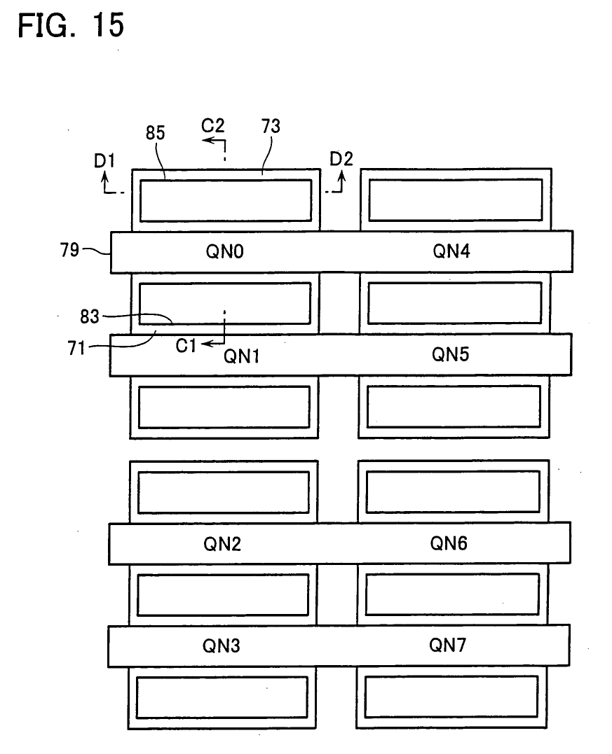

The contact holes 57, 59, 83 and 85 are formed simultaneously by selective removal of the ILD layer 63 in the way stated above. The resulting plan views of these contact holes 57, 59, 83 and 85 are depicted in FIGS. 14 and 15. FIGS. 14 corresponds to FIG. 5, whereas FIG. 15 corresponds to FIG. 6. The contact holes 57 of the source regions 15 are formed so that the contact holes 57 of the source regions 15 of a plurality of memory cells MC that are laid out along a word line WL are coupled together. The contact hole 83, 85 of source/drain region 71, 73 is formed to be longer than the contact hole 59 of drain region 17 when viewing them planarly.

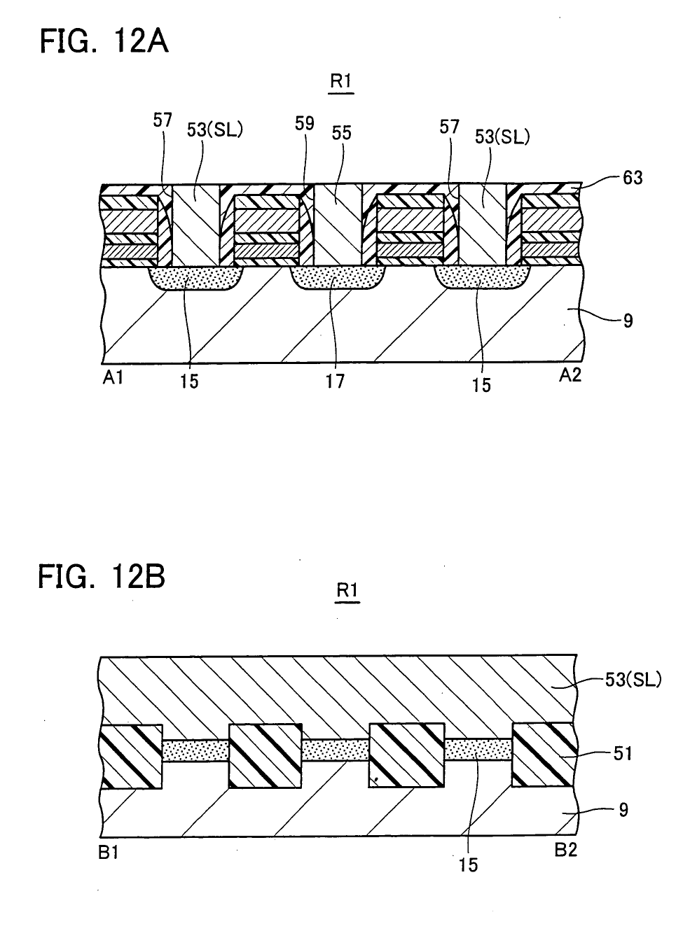

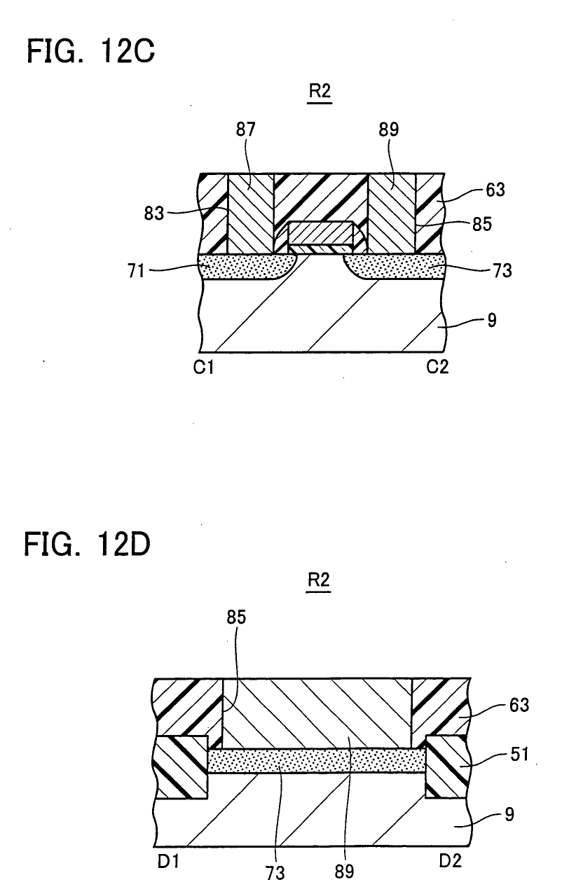

Next, as shown in FIGS. 12A-12D, a layer of tungsten, for example, is formed by sputtering on the ILD layer 63 in such a manner that the contact holes 57, 59, 83 and 85 are buried. Then, this tungsten layer is polished by CMP or the like so that ILD layer 63 is exposed. Whereby, there are performed simultaneously the process steps of i) forming drain-use buried conductors 55 in the contact holes 59 of drain regions 17, ii) forming source-use buried conductors 53 in the contact holes 57 of source regions 15, which conductors become a source line SL for common connection of respective source regions together, and iii) forming source/drain-use buried conductors 87 and 89 in the contact holes 83 and 85 of source/drain regions 71 and 73.

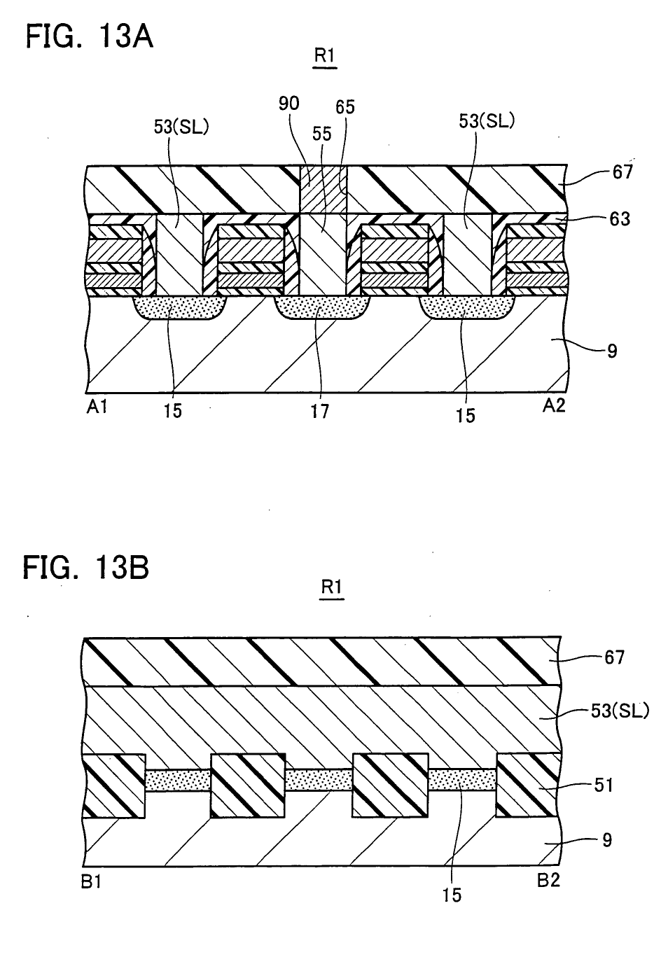

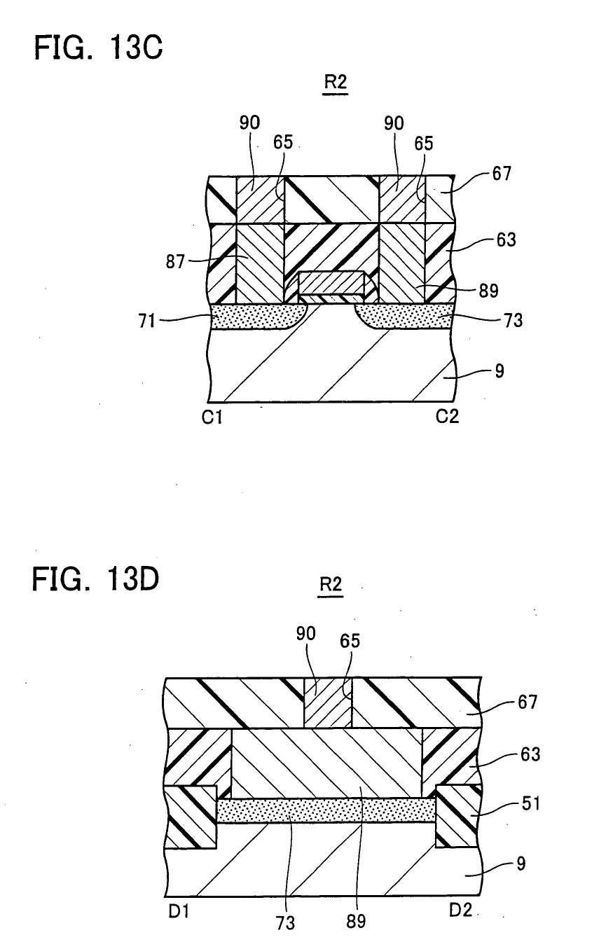

As shown in FIGS. 13A-13D, an ILD layer 67 is formed by CVD for example on the ILD layer 63. The ILD layer 67 may be a silicon oxide film. Then, photolithography and etching processes are performed to form through-holes 65 in the ILD layer 67, thereby causing exposure of the buried conductors 55, 87 and 89. Next, sputtering, for example, is done to form a tungsten layer on ILD layer 67 so that the through-holes 65 are buried. By polishing the resultant structure by CMP, conductive plugs 90 are formed in holes 65. What is done thereafter is a wiring formation process. As shown in FIGS. 7A-7B, bit lines BL which are connected to the conductive plugs 90 are formed on the ILD layer 67.

As explained above, according to the fabrication method of the flash memory in accordance with this embodiment, the local interconnection (LI) layer of memory cells is used for the source/drain-use buried conductors 87 and 89 that are to reduce parasitic capacitance components. Owing to this, it is possible to fabricate parasitic capacitance-reduced column gate transistors QN without having to add any extra manufacturing processes.

### 1C2T/1C3T-NAND Flash Memories

So far, the NOR flash memory in accordance with this embodiment has been discussed. The principles of this embodiment are also applicable to NAND flash memory devices that comprise NAND cells each consisting of a serial combination of memory cells with a source/drain being shared by neighboring ones of the memory cells.

This type of flash memories include a NAND memory chip with what is called the one-cell/two-transistor (1C2T) memory cell structure and a NAND memory with the one-cell/three-transistor (1C3T) cell structure. The 1C2T-NAND flash memory is such that a memory cell unit is made up of a single memory cell transistor and a one select transistor, thereby offering enhanced high-speed accessibility, which is comparable to that of NOR flash memories. The 1C3T-NAND flash memory refers to the one that is arranged so that a memory cell unit consists essentially of a one memory cell transistor and two select transistors with the cell interposed therebetween.

The memory cell and select transistors of the 1C2T/1C3T-NAND memories are substantially the same in structure as those of NAND flash memories. As far as the write/erase principles are concerned, the three types of memories are the same. More specifically, the 1C2T/1C3T-NAND memories are capable of being fabricated by the same process as that of NAND flash memory. Thus it becomes easier to mixedly mount them together on a one chip.

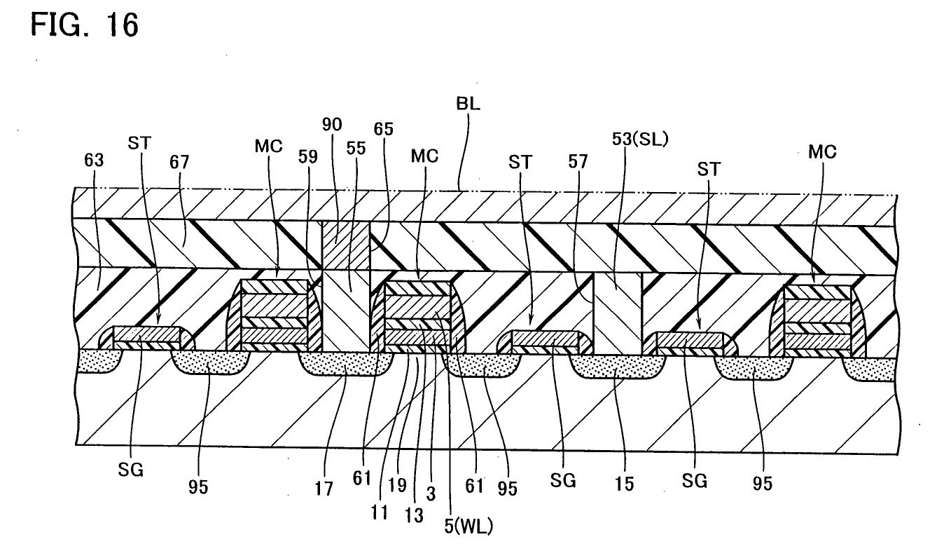

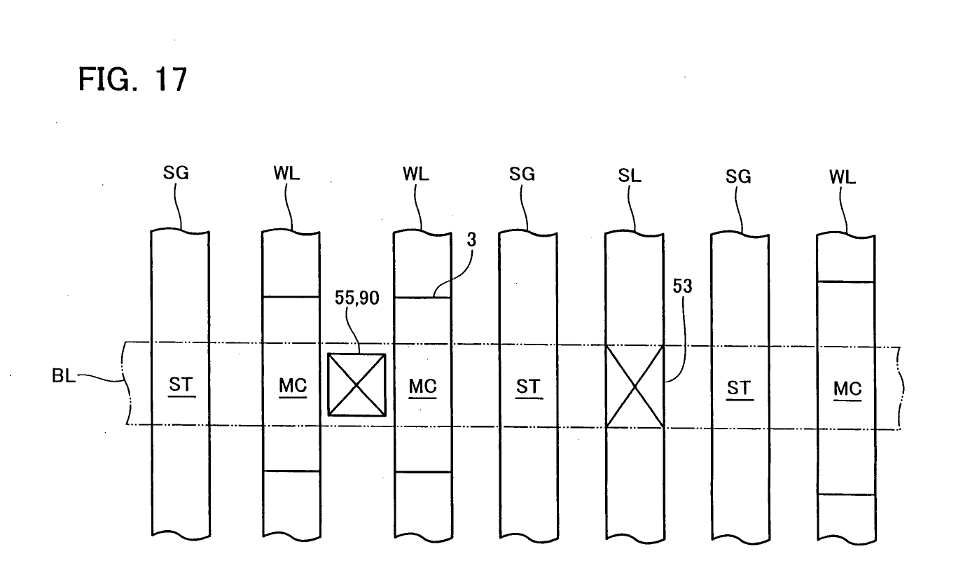

An explanation will first be given of the 1C2T-NAND memory. FIG. 16 is a pictorial representation of a cross-section of part of a cell array of the 1C2T-NAND memory in accordance with this embodiment, wherein this diagram corresponds to FIG. 7A. FIG. 17 shows a planar layout pattern of part of this cell array. A select transistor ST is disposed midway between a memory cell MC and a source-use buried conductive portion 53. The select transistor ST functions as a switch element for connecting them together. Select transistor ST has a source region 15 and an n⁺ type diffusion region 95. This n⁺-diffusion 95 is shared by the select transistor ST and memory cell MC.

The memory cell MC has its drain region 17 at which no select transistor is disposed. This drain 17 is contacted with a drain-use buried conductor 55. Accordingly, the drain region 17 extends to reach a location underlying the side part of a charge storage layer 3. A select gate SG, which is the gate of the select transistor ST, extends in the same direction as that of word lines WL.

Currently available ordinary NOR flash memories are of the one-cell/one-transistor (1C1T) type with each memory cell consisting of a single transistor. Due to this, a threshold voltage distribution for logic “0” data and that for “1” data must be set to have the positive polarity. Accordingly, in view of the fact that a write operation is performed by hot electron injection, there can occur an increase in power consumption and the lack of an ability to write or “program” multiple bits of data at a time.

To avoid these risks, a cell unit of the 1C2T type is proposed. This cell unit is made up of a one memory cell MC and a one select transistor ST that is connected between the cell MC and a source line SL. A feature of this cell unit lies in that it is the same as NAND flash memories in fabrication process and in write/erase principles while offering the features of NOR flash memories. In short, it may be considered in a way that the cell unit is equivalent in structure to a NAND cell unit that is modified to have a one memory cell with its drain-side select transistor being omitted.

Additionally, with the 1C2T-NAND memory, it is possible to perform data write/erase with respect to a memory cell by the flow of an FN tunnel current; for example, the threshold voltage distribution of an erase state (logic “1” state) can be set negative in polarity. Accordingly, when compared to NOR flash memories, the 1C2T-NAND memory offers advantages which follow: an ability to reduce power consumption during writing, an ability to write multiple data bits at a time, no risks as to over-erase problems, and a capability of fabrication by the same process as that of NAND flash memories.

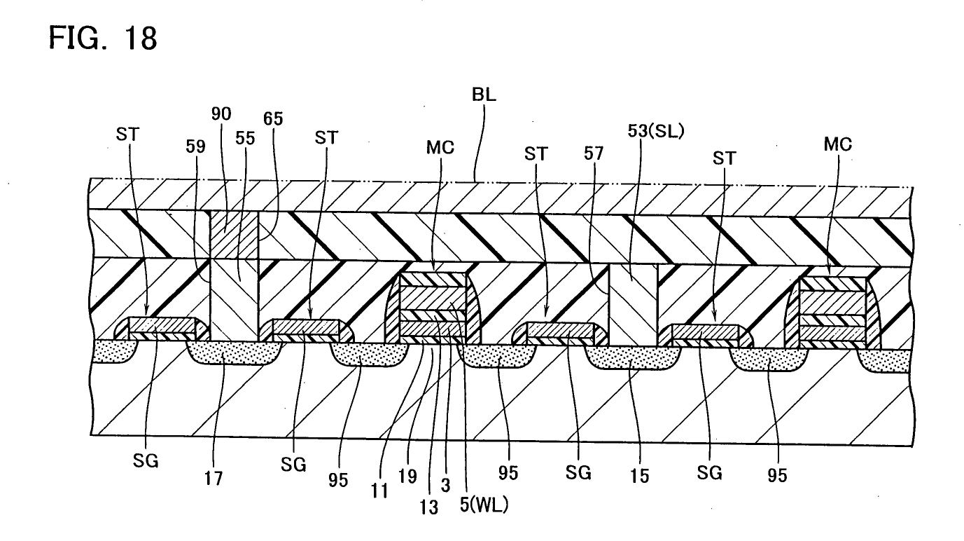

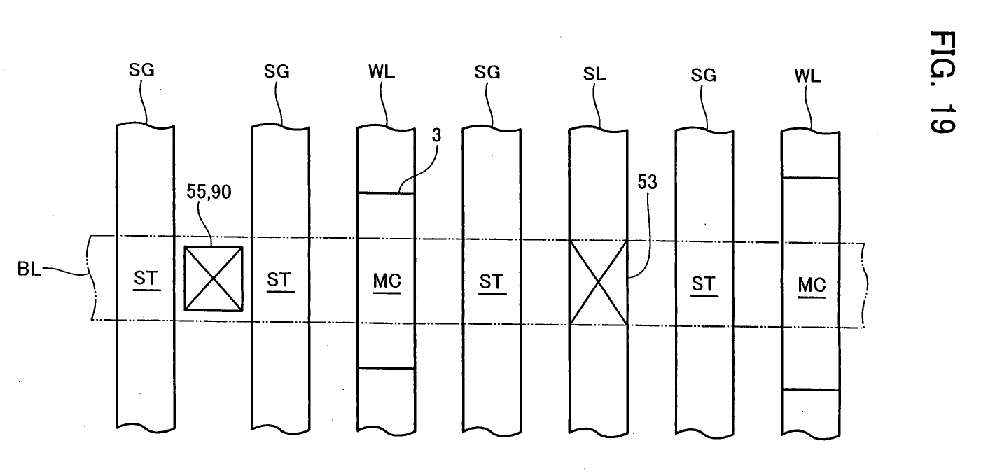

A brief explanation will next be given of a 1C3T-NAND memory. FIG. 18 schematically shows a cross-sectional view of part of a cell array of the 1C3T-NAND type, which view corresponds to FIG. 7A. FIG. 19 is a diagram showing a planar layout pattern of part of this cell array. A first select transistor ST is disposed between a memory cell MC and a source-use buried conductor 53, for serving as a switch element that connects them together. In addition, a second select transistor ST is between the memory cell MC and a drain-use buried conductor 55, for functioning as a switch that connects them together. Thus, the 1C3T-NAND memory is equivalent in structure to a NAND flash memory, except that its NAND cell-constituting series-connected memory cells is replaced with a one memory cell.

As shown in FIGS. 16 and 18, according to the 1C2T and 1C3T-NAND memories in accordance with this embodiment, the source-use buried conductor 53 is used to form a source line SL for common connection of source regions 15 of a plurality of memory cells MC that are disposed along a word line WL. By letting the source-use buried conductor 53 have such the structure, it is possible to reduce the electrical resistance of the source line SL without having to form silicides at the source region 15. Thus it is possible to lessen the loss of a cell current when reading data out of the memory cell MC. This makes it possible to speed up read operations. It should be noted that the 1C2T/1C3T-NAND memory's column gate (one example of peripheral circuitry) is the same as that as has been discussed in the previous section titled “Cell Array and Column Gate Structure.”

### Applying to Electronic Cards and Electronic Devices

As an embodiment, an electric card using the non-volatile semiconductor memory devices according to the above-described embodiments of the present invention and an electric device using the card will be described bellow.

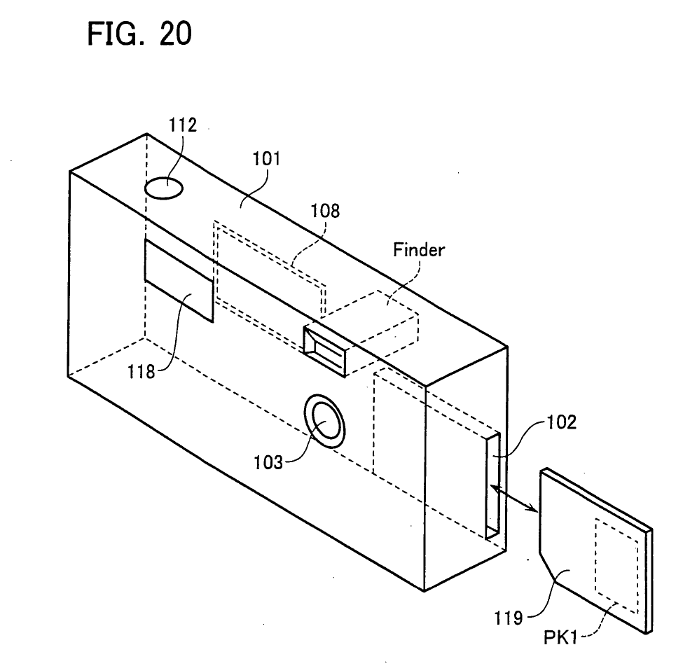

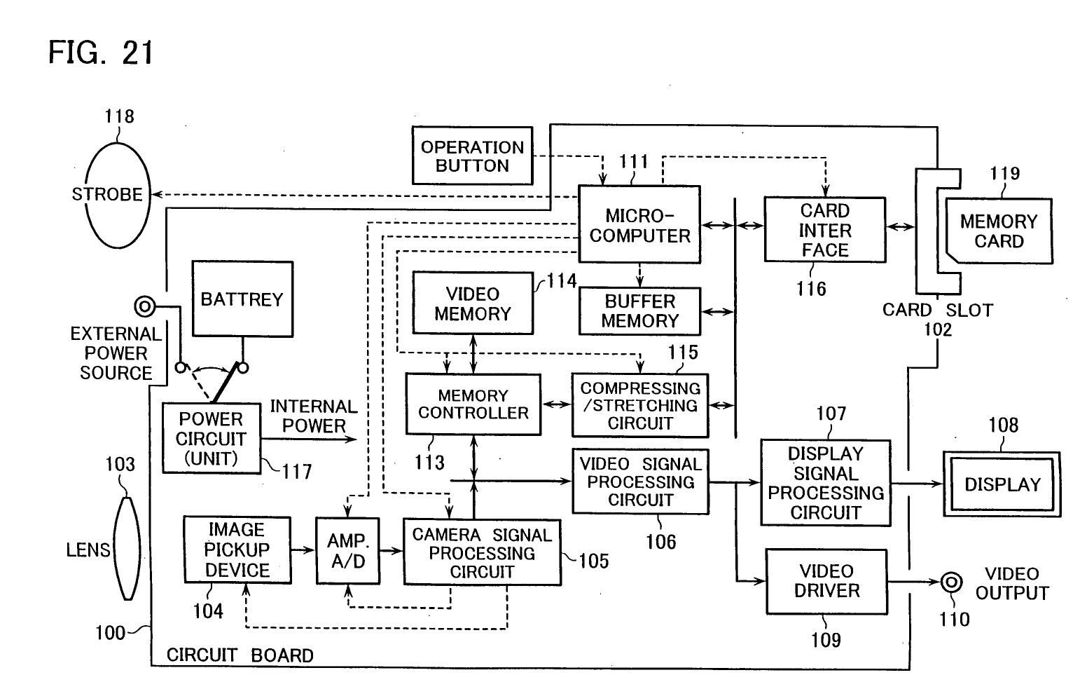

FIG. 20 shows an electric card according to this embodiment and an arrangement of an electric device using this card. This electric device is a digital still camera 101 as an example of portable electric devices. The electric card is a memory card 51 used as a recording medium of the digital still camera 101. The memory card 119 incorporates an IC package PK1 in which the non-volatile semiconductor memory device or the memory system according to the above-described embodiments is integrated or encapsulated.

The case of the digital still camera 101 accommodates a card slot 102 and a circuit board (not shown) connected to this card slot 102. The memory card 119 is detachably inserted in the card slot 102 of the digital still camera 101. When inserted in the slot 102, The memory card 119 is electrically connected to electric circuits of the circuit board.

If this electric card is a non-contact type IC card, it is electrically connected to the electric circuits on the circuit board by radio signals when inserted in or approached to the card slot 102.

FIG. 20 shows a basic arrangement of the digital still camera. Light from an object is converged by a lens 103 and input to an image pickup device 104. The image pickup device 104 is, for example, a CMOS sensor and photoelectrically converts the input light to output, for example, an analog signal. This analog signal is amplified by an analog amplifier (AMP), and converted into a digital signal by an A/D converter (A/D). The converted signal is input to a camera signal processing circuit 105 where the signal is subjected to automatic exposure control (AE), automatic white balance control (AWB), color separation, and the like, and converted into a luminance signal and color difference signals.

To monitor the image, the output signal from the camera processing circuit 105 is input to a video signal processing circuit 106 and converted into a video signal. The system of the video signal is, e.g., NTSC (National Television System Committee). The video signal is input to a display 108 attached to the digital still camera 101 via a display signal processing circuit 107. The display 108 is, e.g., a liquid crystal monitor.

The video signal is supplied to a video output terminal 110 via a video driver 109. An image picked up by the digital still camera 101 can be output to an image apparatus such as a television set via the video output terminal 110. This allows the pickup image to be displayed on an image apparatus other than the display 108. A microcomputer 111 controls the image pickup device 104, analog amplifier (AMP), A/D converter (A/D), and camera signal processing circuit 105.

To capture an image, an operator presses an operation button such as a shutter button 112. In response to this, the microcomputer 111 controls a memory controller 113 to write the output signal from the camera signal processing circuit 105 into a video memory 114 as a flame image. The flame image written in the video memory 114 is compressed on the basis of a predetermined compression format by a compressing/stretching circuit 115. The compressed image is recorded, via a card interface 116, on The memory card 119 inserted in the card slot.

To reproduce a recorded image, an image recorded on The memory card 119 is read out via the card interface 116, stretched by the compressing/stretching circuit 115, and written into the video memory 114. The written image is input to the video signal processing circuit 106 and displayed on the display 108 or another image apparatus in the same manner as when image is monitored.

In this arrangement, mounted on the circuit board 100 are the card slot 102, image pickup device 104, analog amplifier (AMP), A/D converter (A/D), camera signal processing circuit 105, video signal processing circuit 106, display signal processing circuit 107, video driver 109, microcomputer 111, memory controller 113, video memory 114, compressing/stretching circuit 115, and card interface 116.

The card slot 102 need not be mounted on the circuit board 100, and can also be connected to the circuit board 100 by a connector cable or the like.

A power circuit 117 is also mounted on the circuit board 100. The power circuit 117 receives power from an external power source or battery and generates an internal power source voltage used inside the digital still camera 101. For example, a DC-DC converter can be used as the power circuit 117. The internal power source voltage is supplied to the respective circuits described above, and to a strobe 118 and the display 108.

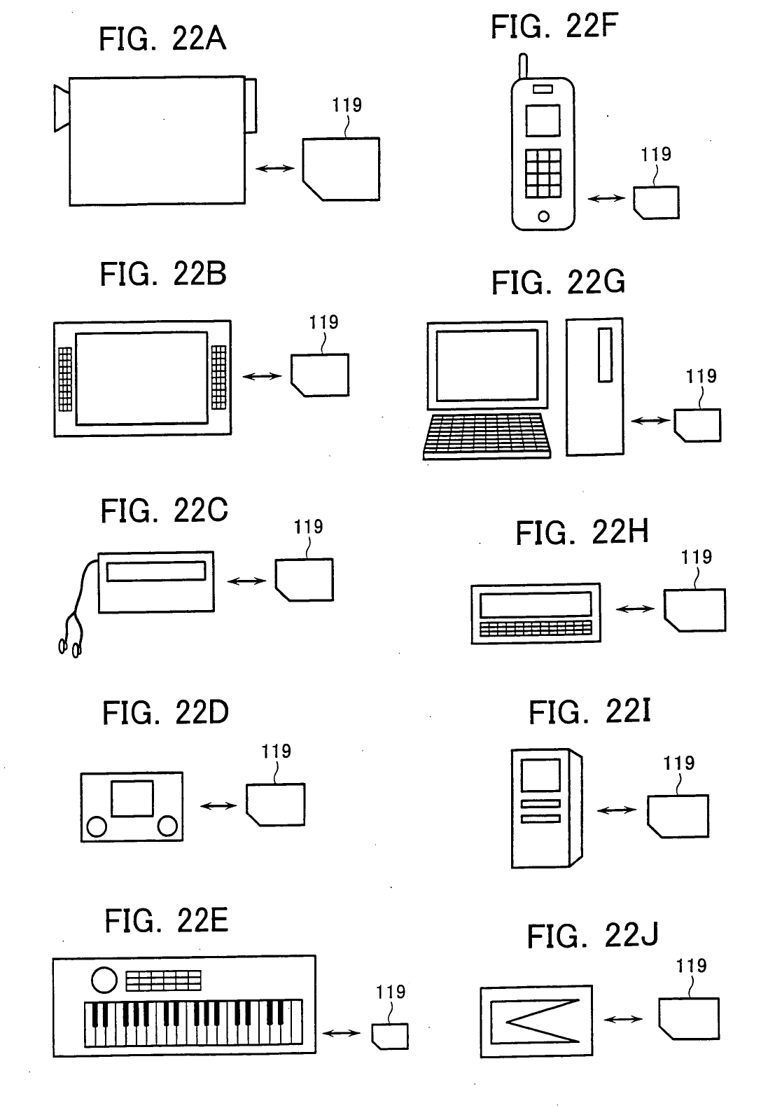

As described above, the electric card according to this embodiment can be used in portable electric devices such as the digital still camera explained above. However, the electric card can also be used in various apparatus such as shown in FIGS. 22A to 22J, as well as in portable electric devices. That is, the electric card can also be used in a video camera shown in FIG. 22A, a television set shown in FIG. 22B, an audio apparatus shown in FIG. 22C, a game apparatus shown in FIG. 22D, an electric musical instrument shown in FIG. 22E, a cell phone shown in FIG. 22F, a personal computer shown in FIG. 22G, a personal digital assistant (PDA) shown in FIG. 22H, a voice recorder shown in FIG. 22I, and a PC card shown in FIG. 22J.

While the present invention has been particularly shown and described with reference to the embodiments, it will be understood by those skilled in the art that various changes in form and detail may be made without departing from the spirit, scope, and teachings of the invention.

1. A nonvolatile semiconductor memory device comprising:
an array of electrically data rewritable nonvolatile memory cells each having spaced-apart source and drain regions formed in a cell array area of a semiconductor substrate, an electrical charge storage layer formed above a channel region between the source and drain regions, and a control gate overlying the charge storage layer;
a source line for common connection of source regions of a plurality of ones of said memory cells disposed along a word line by source-use buried conductive portions as buried in mutually connected contact holes of said source regions;
drain-use buried conductive portions buried in contact holes of drain regions of said plurality of ones of said memory cells;
a transistor having a pair of spaced-apart source/drain regions formed in a peripheral circuit area of said semiconductor substrate and a gate electrode formed over a channel region between the source/drain regions; and
source/drain-use buried conductive portions buried in contact holes of said source/drain regions and formed to be longer than said drain-use buried conductive portions when looking at them planarly.

2. The device according to claim 1, wherein said source/drain-use buried conductive portion has a rectangular plane.

3. The device according to claim 2, wherein each said drain-use buried conductive portion has a square plane, and wherein a length of one side of this plane is substantially the same as a length of a short side of said source/drain-use buried conductive portion.

4. The device according to claim 1, wherein said source/drain-use buried conductive portion extends in a direction in which said gate electrode extends.

5. The device according to claim 1, wherein said source-use buried conductive portions and said drain-use buried conductive portions and said source/drain-use buried conductive portions include a high-melting point metal layer.

6. The device according to claim 1, wherein said source-use buried conductive portions and said drain-use buried conductive portions and said source/drain-use buried conductive portions include a local interconnection layer.

7. The device according to claim 1, wherein said transistor of said peripheral circuit area is a component of at least one of decoder and column gate circuits.

8. The device according to claim 1, wherein a wiring-use buried conductive portion at the same layer of said source/drain-use buried conductive portion is formed above an element isolation dielectric layer of said peripheral circuit area.

9. The device according to claim 1, further comprising:
bit lines connected to said drain-use buried conductive portions.

10. The device according to claim 1, wherein said nonvolatile semiconductor memory device is a NOR type electrically erasable programmable read only memory (EEPROM).

11. The device according to claim 1, wherein said memory cells are capable of performing a write operation for injecting into said charge storage layer hot electrons created near said drain region.

12. The device according to claim 1, wherein said source region connected to said source-use buried conductive portion and said drain region connected to said drain-use buried conductive portion extend to lie beneath side portions of said charge storage layer, respectively.

13. The device according to claim 1, wherein
a select transistor is disposed between said memory cell and said source-use buried conductive portion for serving as a switch for connecting them together, and
said drain region in contact with said drain-use buried conductive portion extends to lie below a side portion of said charge storage layer.

14. The device according to claim 1, wherein
a first select transistor is disposed between said memory cell and said source-use buried conductive portion for serving as a switch for connecting them together, and
a second select transistor is disposed between said memory cell and said drain-use buried conductive portion for acting as a switch for connecting them together.

15. An electronic card equipped with a nonvolatile semiconductor memory device, said device comprising:
an array of electrically data rewritable nonvolatile memory cells each having spaced-apart source and drain regions formed in a cell array area of a semiconductor substrate, an electrical charge storage layer formed above a channel region between the source and drain regions, and a control gate overlying the charge storage layer;
a source line for common connection of source regions of a plurality of ones of said memory cells disposed along a word line by source-use buried conductive portions as buried in mutually connected contact holes of said source regions;
drain-use buried conductive portions buried in contact holes of drain regions of said plurality of ones of said memory cells;
a transistor having a pair of spaced-apart source/drain regions formed in a peripheral circuit area of said semiconductor substrate and a gate electrode formed over a channel region between the source/drain regions; and
source/drain-use buried conductive portions buried in contact holes of said source/drain regions and formed to be longer than said drain-use buried conductive portions when looking at them planarly.

16. An electronic device comprising:
a card interface;
a card slot connected to said card interface; and
said electronic card defined in claim 15 for being electrically connectable to said card slot.

17. The device according to claim 16, wherein said electronic device is a digital camera.

18. A nonvolatile semiconductor memory device comprising:
an array of electrically data rewritable nonvolatile memory cells each having spaced-apart source and drain regions formed in a cell array area of a semiconductor substrate, an electrical charge storage layer formed above a channel region between the source and drain regions, and a control gate overlying the charge storage layer;
a source line for common connection of source regions of a plurality of ones of said memory cells disposed along a word line by source-use buried conductive portions as buried in mutually connected contact holes of said source regions;
drain-use buried conductive portions buried in contact holes of drain regions of said plurality of ones of said memory cells;
a transistor having a pair of spaced-apart source/drain regions formed in a peripheral circuit area of said semiconductor substrate and a gate electrode formed over a channel region between the source/drain regions; and
source/drain-use buried conductive portions being buried in contact holes of said source/drain regions and having a rectangular plane.

19. A nonvolatile semiconductor memory device comprising:
an array of electrically data rewritable nonvolatile memory cells each having spaced-apart source and drain regions formed in a cell array area of a semiconductor substrate, an electrical charge storage layer formed above a channel region between the source and drain regions, and a control gate overlying the charge storage layer;
a source line for common connection of source regions of a plurality of ones of said memory cells disposed along a word line by source-use buried conductive portions as buried in mutually connected contact holes of said source regions;
drain-use buried conductive portions buried in contact holes of drain regions of said plurality of ones of said memory cells; and
a select transistor disposed between said memory cell and said source-use buried conductive portion for acting as a switch for connecting them together, wherein
said drain region in contact with one of said drain-use buried conductive portions extends to lie beneath a side portion of said electrical charge storage layer.

20. A nonvolatile semiconductor memory device comprising:
an array of electrically data rewritable nonvolatile memory cells each having spaced-apart source and drain regions formed in a cell array area of a semiconductor substrate, an electrical charge storage layer formed above a channel region between the source and drain regions, and a control gate overlying the charge storage layer;
a source line for common connection of source regions of a plurality of ones of said memory cells disposed along a word line by source-use buried conductive portions as buried in mutually connected contact holes of said source regions;
drain-use buried conductive portions buried in contact holes of drain regions of said plurality of ones of said memory cells;
a first select transistor is disposed between said memory cell and said source-use buried conductive portion for serving as a switch for connecting them together; and
a second select transistor is disposed between said memory cell and said drain-use buried conductive portion for acting as a switch for connecting them together.

21. A method for fabricating a nonvolatile semiconductor memory device, comprising:
forming electrically data rewritable nonvolatile memory cells each having spaced-apart source and drain regions formed in a cell array area of a semiconductor substrate, an electrical charge storage layer formed above a channel region between the source and drain regions, and a control gate overlying the charge storage layer and while substantially simultaneously forming a transistor having a pair of spaced-apart source/drain regions formed in a peripheral circuit area of said semiconductor substrate and a gate electrode formed over a channel region defined between the source/drain regions;
forming an interlayer dielectric layer above said semiconductor substrate in such a manner as to cover said memory cells and said transistor;
simultaneously performing, by selective removal of said interlayer dielectric layer, formation of contact holes at said drain regions, formation of contact holes at said source regions of a plurality of ones of said memory cells which are laid out along a word line so that the contact holes are coupled together, and formation of contact holes at said source/drain region, which contact holes are longer than the contact holes of said drain regions when looking at them planarly; and
simultaneously performing formation of drain-use buried conductive portions in the contact holes of said drain regions, formation of source-use buried conductive portions for use as a source line for common connection of respective source regions in the contact holes of said source regions of the plurality of ones of said memory cells, and formation of source/drain-use buried conductive portions in the contact holes of said source/drain regions.

22. The method according to claim 21, wherein said step of simultaneously performing formation of contact holes includes forming a wiring groove above an element isolation dielectric layer of said peripheral circuit area by selective removal of said interlayer dielectric layer, and wherein
said step of simultaneously performing formation of buried conductive portions includes forming a wiring-use buried conductive portion in said wiring groove.

23. The method according to claim 21, further comprising, after said step of simultaneously performing formation of buried conductive portions:
forming another interlayer dielectric layer above said interlayer dielectric layer; and
forming, on said another interlayer dielectric layer, bit lines for connection to said drain-use buried conductive portions.

24. A method for fabricating a nonvolatile semiconductor memory device, comprising:
forming electrically data rewritable nonvolatile memory cells each having spaced-apart source and drain regions formed in a cell array area of a semiconductor substrate, an electrical charge storage layer formed above a channel region between the source and drain regions, and a control gate overlying the charge storage layer and while substantially simultaneously forming a transistor having a pair of spaced-apart source/drain regions formed in a peripheral circuit area of said semiconductor substrate and a gate electrode formed over a channel region defined between the source/drain regions;
forming an interlayer dielectric layer above said semiconductor substrate in such a manner as to cover said memory cells and said transistor;
simultaneously performing, by selective removal of said interlayer dielectric layer, formation of contact holes at said drain regions, formation of contact holes at said source regions of a plurality of ones of said memory cells which are laid out along a word line so that the contact holes are coupled together, and formation of contact holes each having a rectangular plane at said source/drain region; and
simultaneously performing formation of drain-use buried conductive portions in the contact holes of said drain regions, formation of source-use buried conductive portions for use as a source line for common connection of respective source regions in the contact holes of said source regions of the plurality of ones of said memory cells, and formation of source/drain-use buried conductive portions in the contact holes of said source/drain regions.
